(19) United States
(12) Patent Application Publication
(10) Pub. No.: US 2025/0309941 A1
(43) Pub. Date: Oct. 2, 2025

(54) SEMICONDUCTOR PROCESS LOGISTICS CONTROLLING SYSTEM USING POWER LINE COMMUNICATION

(71) Applicant: Cantops co.ltd, Suwon-si Gyeonggi-do (KR)

(72) Inventors: Hak Seo OH, Yongin-si Gyeonggi-do (KR); Sung Ik KIM, Hwaseong-si Gyeonggi-do (KR); Young Deok RYU, Suwon-si Gyeonggi-do (KR); Hee Hyun SEO, Gunpo-si Gyeonggi-do (KR); Chang Hoon MOON, Suwon-si Gyeonggi-do (KR); Seong Kyeong EEO, Suwon-si Gyeonggi-do (KR); Jung Kyu KIM, Osan-si Gyeonggi-do (KR); Byeong Geun LIM, Suwon-si Gyeonggi-do (KR); Jin Hwan KO, Seoul (KR); Sang Kyo AHN, Suwon-si Gyeonggi-do (KR); Sang Gyu HAN, Suwon-si Gyeonggi-do (KR)

(73) Assignee: Cantops co.ltd, Suwon-si Gyeonggi-do (KR)

(21) Appl. No.: 19/083,720

(22) Filed: Mar. 19, 2025

(30) Foreign Application Priority Data
Mar. 26, 2024 (KR) 10-2024-0041314
Oct. 31, 2024 (KR) 10-2024-0152435

(51) Int. Cl. H04B 3/54

(52) U.S. Cl. CPC H04B 3/54

(57) ABSTRACT

The present disclosure relates to a semiconductor process logistics management system, and more particularly to, a semiconductor process logistics management system using power line communication. The present disclosure includes a slave control device configured to perform control for an item storage device in which an item is stored, a power line communication line configured to deliver power and a communication signal to the slave control device, and a master control device connected to the power line communication line and configured to communicate with the slave control device through the power line communication line, and the slave control device includes an identification module capable of communicating with the identification tag of the item stored in the item storage device.

### CROSS REFERENCE TO RELATED APPLICATIONS

The present application claims priority of Korean Patent Application No. 10-2024-0041314 filed on Mar. 26, 2024 and Korean Patent Application No. 10-2024-0152435 filed on Oct. 31, 2024, the entire contents of which is incorporated herein for all purposes by this reference.

### BACKGROUND OF THE DISCLOSURE

### Field of the Disclosure

The present disclosure relates to a semiconductor process logistics management system, and more specifically, to a semiconductor process logistics management system using power line communication.

### Description of the Related Art

With the introduction of an automatic logistics management system into a semiconductor process line, transport vehicles are used to transport and load wafers.

On the side of the moving path of the transport vehicles of the automatic logistics management system, there are buffers (item storage devices) that temporarily store the wafer carriers while a wafer transport vehicle transports the wafer carriers, and if the location of a buffer and the wafer carrier therein are identified, movement of the wafer transport vehicle may be efficiently managed when the transport vehicle intends to load a new wafer carrier into the buffer or to transport the wafer carrier loaded in the buffer. In addition, information about the wafer carriers loaded in the buffers plays a critical role in managing a semiconductor process.

### Document of Related Art

### Patent Document

(Patent Document 1) Korean Patent Application Publication No. 10-2012-0105269 (Sep. 25, 2012)

### SUMMARY OF THE DISCLOSURE

The present disclosure has been made in an effort to provide a semiconductor process logistics management system that can reduce cost and minimize management cost by providing power supply and communication lines using only existing power lines for power supply and by removing EtherCAT communication cables for communication of an item storage device from the existing semiconductor process logistics system.

To achieve the above-mentioned object, the present disclosure provides a semiconductor process logistic management system including a slave control device configured to control an item storage device in which an item is stored; a power line communication line configured to deliver power and a communication signal to the slave control device; a master control device connected to the power line communication line and configured to communicate with the slave control device through the power line communication line; and a filter unit disposed on the power line communication line and configured to block the communication signal, and based on the filter unit, a power applied section in which only the power is applied and a power-communication signal applied section in which the power and the communication signal are applied are formed on the power line communication line.

In addition, the slave control device and the master control device may be connected to the power-communication signal applied section of the power line communication line, the slave control device may include a slave-side power line communication module configured to separate the power and the communication signal supplied from the power line communication line and to transmit and receive the communication signal, and the master control device may include a master-side power line communication module configured to separate the power and the communication signal supplied from the power line communication line and to transmit and receive the communication signal to and from the power line communication line.

In addition, the slave control device may further include an identification module capable of communicating with an identification tag of the item stored in the item storage device, a slave-side power supply module configured to receive the power from the slave-side power line communication module, a gas supply control module configured to control supply of inert gas for the item storage device, a slave-side central control module configured to control the identification module and the gas supply control module, and a slave-side sensor module configured to sense states of components, the slave-side power line communication module may include a coupler unit configured to receive the power and the communication signal from the power line communication line and to supply the power to the slave-side power supply module and a slave-side power line communication transceiver unit configured to receive the communication signal from the coupler unit or to deliver the communication signal to the coupler unit, and the identification module may include one or more antenna units on an identification module side, configured to perform wireless communication with the identification tag, and an identification module control unit configured to supply power to the identification tag and to transmit and receive an identification signal through the antenna unit on the identification module side.

In addition, the identification module control unit may include a carrier wave generation block configured to generate a carrier wave and a control command, an antenna selection block configured to designate any one of the connected one or more antenna units on the identification module side and to select a port to which the antenna unit is connected, a power monitoring block configured to monitor the power transmitted from the antenna unit, and a capacitor selection block configured to match impedance that varies due to an external influence and a coil value deviation in the antenna unit.

In addition, the slave control device may further include a slave-side switching unit configured to selectively block the power and the communication signal delivered from the power line communication line to the slave-side power line communication module, the slave-side power supply module, which receives the power from the coupler unit, may generate power monitoring data about a state of the power and deliver the power monitoring data to the slave-side central control module, the slave-side power line communication transceiver unit may deliver power line communication monitoring data about the communication signal to the slave-side central control module, the slave-side central control module may determine whether the power is normal or abnormal based on the power monitoring data and determine whether the communication signal is normal or abnormal based on the power line communication monitoring data, and the slave-side central control module may transmit a blocking control signal to the slave-side switching unit such that the slave-side switching unit blocks the power and the communication signal, supplied from the power line communication line to the slave-side power line communication module, when at least one of the power and the communication signal is determined to be abnormal.

In addition, the slave-side power line communication module may comprise multiple slave-side power line communication modules, each of which is individually connected to the slave-side power supply module and the slave-side central control module, and the slave control device may include a switching module configured to selectively connect any one of the multiple slave-side power line communication modules to the power line communication line.

In addition, the master control device may further include a master-side power supply module configured to receive the power from the master-side power line communication module, a master-side central control module configured to control the master control device, an external power supply module configured to selectively receive power from an external power supply unit, and a master-side sensor module configured to sense states of components, and the master-side power line communication module may include a coupler unit configured to receive the power and the communication signal from the power line communication line and to supply the power to the master-side power supply module and a master-side power line communication transceiver unit configured to receive the communication signal from the coupler unit or to deliver the communication signal to the coupler unit.

In addition, the master control device may further include a master-side communication module connected to an external server and configured to receive a control signal from the external server.

In addition, the master control device may further include a control signal transceiver module connected to an external server and configured to receive a control signal from the external server, the control signal transceiver module may include a power supply unit on a control signal transceiver module side, connected to the power applied section of the power line communication line and configured to receive the power, and a communication unit on the control signal transceiver module side, configured to transmit and receive the control signal, and the master control device may further include a master-side communication unit configured to transmit and receive the control signal to and from the control signal transceiver module.

In addition, the master-side power line communication module may comprise multiple master-side power line communication modules, each of which is individually connected to the master-side power supply module and the master-side central control module, and the master control device may further include a switching module configured to selectively connect any one of the multiple master-side power line communication modules to the power line communication line.

In addition, the master-side power line communication transceiver unit of the master-side power line communication module may include a switching unit on a communication unit side, configured to selectively block the communication signal delivered from the coupler unit, the master-side power line communication transceiver unit may deliver power line communication monitoring data about the communication signal to the master-side central control module, the master-side central control module may determine whether the communication signal is normal or abnormal based on the power line communication monitoring data, and the master-side central control module may transmit a communication signal blocking control signal to the master-side power line communication transceiver unit such that the switching unit on the communication unit side blocks the communication signal when the communication signal is determined to be abnormal.

In addition, the master-side power supply module may include a switching unit on a power supply module side, configured to selectively block the power delivered from the coupler unit, and a power monitoring unit configured to generate power monitoring data about a state of the power and to deliver the power monitoring data to the master-side central control module, the master-side central control module may determine whether the power is normal or abnormal based on the power monitoring data, the master-side central control module may transmit a power blocking control signal to the master-side power supply module such that the switching unit on the power supply module side blocks the power when the power is determined to be abnormal, and the switching unit on the power supply module side and the switching unit on the communication unit side may block the power and the communication signal independently of each other.

In addition, the master control device may further include a master-side switching unit configured to selectively block the power and the communication signal delivered from the power line communication line to the master-side power line communication module, the master-side power supply module, which receives the power from the coupler unit, may generate power monitoring data about a state of the power and deliver the power monitoring data to the master-side central control module, the master-side power line communication transceiver unit may deliver power line communication monitoring data about the communication signal to the master-side central control module, the master-side central control module may determine whether the power is normal or abnormal based on the power monitoring data and determine whether the communication signal is normal or abnormal based on the power line communication monitoring data, and the master-side central control module may transmit a blocking control signal to the master-side switching unit such that the master-side switching unit blocks the power and the communication signal, supplied from the power line communication line to the master-side power line communication module, when at least one of the power and the communication signal is determined to be abnormal.

In addition, the power-communication signal applied section of the power line communication line may be provided between a first power applied section and a second power applied section of the power applied section, and the filter unit may include a first filter unit disposed in a node to which the power-communication signal applied section and the first power applied section are connected and a second filter unit disposed in a node to which the power-communication signal applied section and the second power applied section are connected.

In addition, the semiconductor process logistics management system may further include an external device connected to the power line communication line of the power-communication signal applied section and configured to receive only the power, and the filter unit may include a third filter unit between the external device and a node to which the power line communication line of the power-communication signal applied section is connected.

In addition, the master control device may include a first master control device connected to any one node on the power line communication line and a second master control device connected to an additional node other than the node to which the first master control device is connected, only any one of the first master control device and the second master control device may perform communication with the slave control device, the remaining one of the first master control device and the second master control device may monitor whether the master control device performing communication with the slave control device normally operates, and when the master control device performing communication with the slave control device does not perform normal operation, the connection between the master control device performing communication with the slave control device and the power line communication line may be disconnected, and the remaining master control device may start communication with the slave control device.

The present disclosure also provides a slave control device configured to perform control for an item storage device in which an item is stored, the slave control device including a slave-side power line communication module configured to separate power and a communication signal supplied from a power line communication line and to transmit and receive the communication signal; a slave-side power supply module configured to receive the power from the slave-side power line communication module; and a slave-side sensor module configured to sense states of components, and the slave-side power line communication module includes a coupler unit configured to receive the power and the communication signal from the power line communication line and to supply the power to the slave-side power supply module and a slave-side power line communication transceiver unit configured to receive the communication signal from the coupler unit or to deliver the communication signal to the coupler unit.

In addition, the slave control device may further include a gas supply control module configured to control supply of inert gas for the item storage device; an identification module capable of communicating with an identification tag of the item stored in the item storage device; and a slave-side central control module configured to control the identification module and the gas supply control module, and the identification module may include one or more antenna units on an identification module side, configured to perform wireless communication with the identification tag, and an identification module control unit configured to supply power to the identification tag and transmit and receive an identification signal through the antenna unit on the identification module side.

In addition, the identification module control unit may include a carrier wave generation block configured to generate a carrier wave and a control command, an antenna selection block configured to designate any one of the connected one or more antenna units on the identification module side and to select a port to which the antenna unit is connected, a power monitoring block configured to monitor power transmitted from the antenna unit, and a capacitor selection block configured to match impedance that varies due to an external influence and a coil value deviation in the antenna unit.

The present disclosure also provides a master control device configured to communicate with a slave control device, which performs control for an item storage device in which an item is stored, through a power line communication line, the master control device including a master-side power line communication module configured to separate power and a communication signal supplied from the power line communication line and to transmit and receive the communication signal to and from the power line communication line; a master-side power supply module configured to receive the power from the master-side power line communication module; a master-side central control module configured to control the master control device; an external power supply module configured to selectively receive power from an external power supply unit; and a master-side sensor module configured to sense states of components, and the master-side power line communication module includes a coupler unit configured to receive the power and the communication signal from the power line communication line and to supply the power to the master-side power supply module and a master-side power line communication transceiver unit configured to receive the communication signal from the coupler unit or to deliver the communication signal to the coupler unit.

In addition, the master control device may further include a master-side communication module connected to an external server and configured to receive a control signal from the external server.

In addition, the master control device may further include a control signal transceiver module connected to an external server and configured to receive a control signal from the external server and a master-side communication unit configured to transmit and receive the control signal to and from the control signal transceiver module, and the control signal transceiver module may include a power supply unit on a control signal transceiver module side, connected to a power applied section of the power line communication line and configured to receive the power, and a communication unit on the control signal transceiver module side, configured to transmit and receive the control signal.

In addition, the master-side power line communication module may comprise multiple master-side power line communication modules, each of which is individually connected to the master-side power supply module and the master-side central control module, and the master control device may further include a switching module configured to selectively connect any one of the multiple master-side power line communication modules to the power line communication line.

### BRIEF DESCRIPTION OF THE DRAWINGS

FIG. 1 is a diagram schematically illustrating a semiconductor process logistics management system according to an embodiment of the present disclosure.

FIG. 2 is a diagram illustrating the semiconductor process logistics management system of FIG. 1 in more detail.

FIG. 3 is a diagram illustrating the master control device of the semiconductor process logistics management system of FIG. 1.

FIG. 4 is a diagram illustrating the slave control device of the semiconductor process logistics management system of FIG. 1.

FIG. 5 is a diagram illustrating the identification module control unit of the semiconductor process logistics management system of FIG. 4 in detail.

FIG. 6 is a diagram illustrating a semiconductor process logistics management system according to another embodiment of the present disclosure.

FIG. 7 is a diagram illustrating a semiconductor process logistics management system according to a further embodiment of the present disclosure.

FIG. 8 is a diagram illustrating a semiconductor process logistics management system according to yet another embodiment of the present disclosure.

FIG. 9 is a diagram illustrating a semiconductor process logistics management system according to still another embodiment of the present disclosure.

FIG. 10 is a diagram illustrating a semiconductor process logistics management system according to still another embodiment of the present disclosure.

FIG. 11 is a diagram illustrating the master control device of a semiconductor process logistics management system according to still another embodiment of the present disclosure.

FIG. 12 is a diagram illustrating the master control device of a semiconductor process logistics management system according to still another embodiment of the present disclosure.

### DETAILED DESCRIPTION OF THE DISCLOSURE

The advantages and features of the present disclosure, as well as methods for achieving them, will become apparent by referring to embodiments described in detail below in conjunction with the accompanying drawings. However, the present disclosure is not limited to the embodiments disclosed herein and can be implemented in various other forms. The embodiments of the present disclosure are intended to fully describe the present disclosure, and to fully inform those skilled in the art, to which the present disclosure pertains, of the scope of the disclosure. The present disclosure is defined only by the scope of the accompanying claims.

Although terms such as “first” and “second” are used to describe various components, it is apparent that these terms are not intended to limit the components. These terms are merely used to distinguish one component from another. Therefore, it is apparent that a first component described below may be a second component within the technical scope of the present disclosure.

Throughout the specification, the same reference numerals refer to the same components.

The features of various embodiments of the present disclosure may be combined or integrated either partially or entirely. As will be readily understood by those skilled in the art, various technical interconnections and operations are possible. Respective embodiments may be implemented independently or in conjunction with each other in a relational context.

Meanwhile, any potential effects that can be expected based on the technical features of the present disclosure but are not explicitly mentioned in the specification of the present disclosure should be considered as described herein. The embodiments are provided to more fully explain the present disclosure to those skilled in the art. The contents shown in the drawings may be exaggerated and represented compared to the actual implementation of the disclosure. Detailed descriptions of configurations which have been deemed to make the gist of the present disclosure unnecessarily obscure will be omitted or briefly made.

Hereinafter, embodiments of the present disclosure will be described in detail with reference to the accompanying drawings.

In an existing semiconductor process logistics management system, a slave control device for monitoring and controlling item storage units of an item storage device and a master control device for controlling the slave control device are connected via EtherCAT. Also, a separate power supply line is required to supply power to the slave control device and the master control device. Here, because a communication line for communication and a power supply line are arranged in a limited space, there is a limitation on the installation space, and excessive cost and time are consumed for installation and maintenance.

Accordingly, in order to solve the problems of the existing system, the inventor of the present disclosure proposes the following configuration.

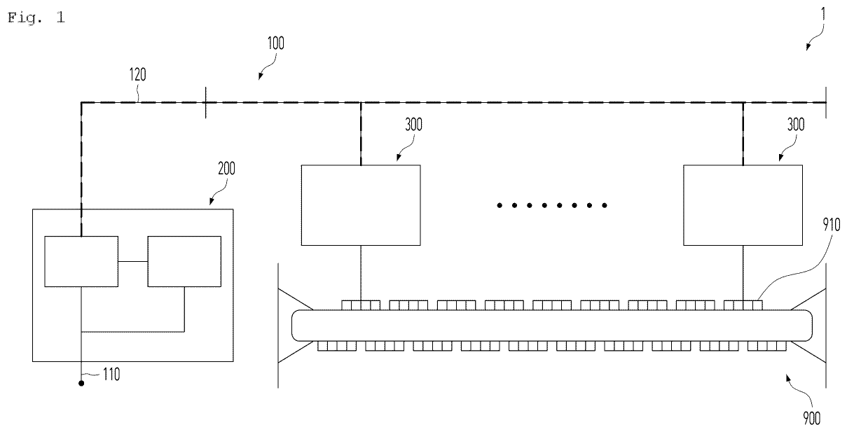

FIG. 1 is a diagram schematically illustrating a semiconductor process logistics management system according to an embodiment of the present disclosure.

Referring to FIG. 1, the semiconductor process logistics management system 1 according to an embodiment of the present disclosure is proposed to solve the problems of the existing system, which requires a communication line and a power line separately, and it is configured such that a master control device 200 and a slave control device 300 deliver communication signals using a power line communication line 100. That is, the master control device 200 and the slave control device 300 may receive power from the power line communication line 100 and may transmit and receive communication signals. In the present embodiment, one or more power line communication lines 100 may be provided, and when multiple power line communication lines 100 are provided, the power line communication lines 100 may be connected in parallel to each other.

The slave control device 300 receives the power from the power line communication line 100 and transmits and receives the communication signal, thereby performing identification control of items (e.g., the Front Opening Unified Pod (FOUP) loaded with wafers, etc.) and inert gas supply control for the item storage units 910 of an item storage device 900.

Hereinafter, the configuration of the semiconductor process logistics management system 1 according to an embodiment of the present disclosure will be described in more detail.

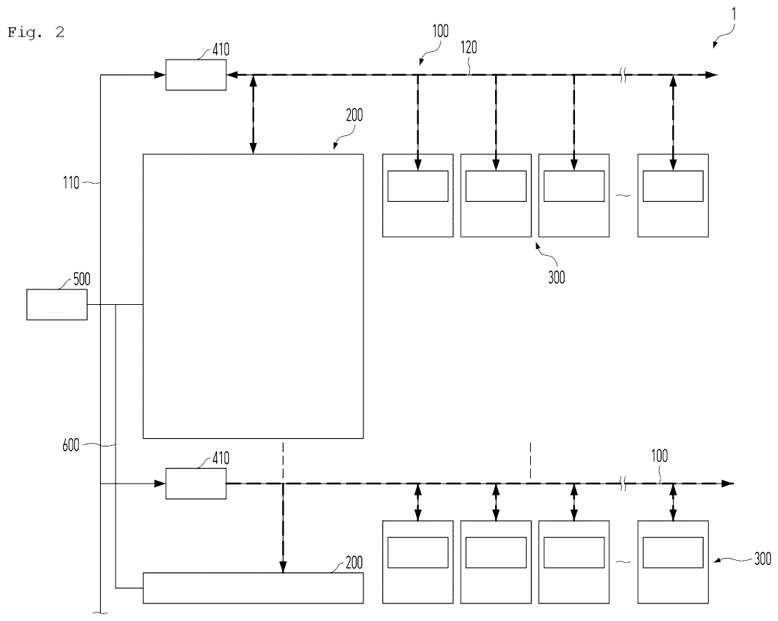

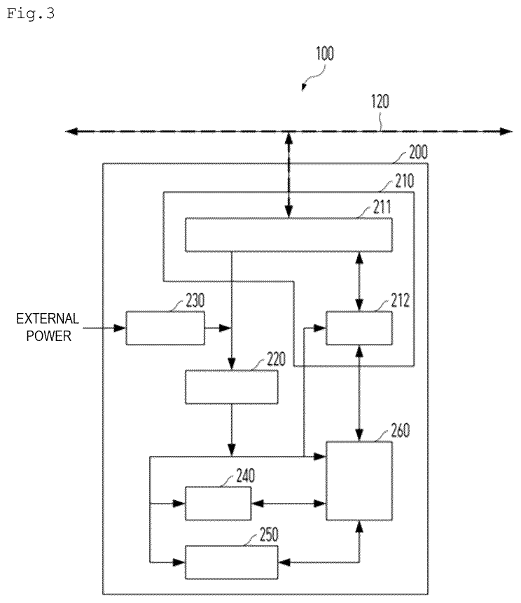

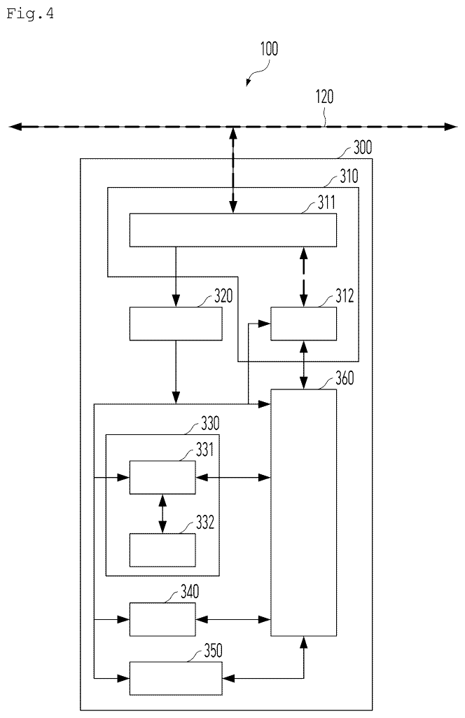

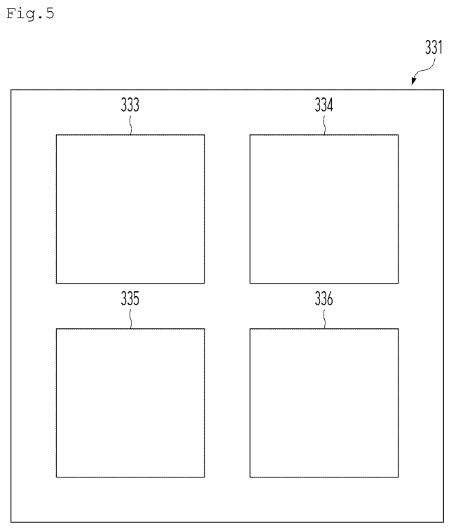

FIG. 2 is a diagram illustrating the semiconductor process logistics management system of FIG. 1 in more detail, and FIG. 3 is a diagram illustrating the master control device of the semiconductor process logistics management system of FIG. 1. Also, FIG. 4 is a diagram illustrating the slave control device of the semiconductor process logistics management system of FIG. 1, and FIG. 5 is a diagram illustrating the identification module control unit of the semiconductor process logistics management system of FIG. 4 in detail.

Referring to FIGS. 2 to 5, the semiconductor process logistics management system according to the present embodiment includes a slave control device 300 configured to control an item storage device 900 in which items are stored, a power line communication line 100 configured to deliver power and a communication signal to the slave control device 300, a master control device 200 connected to the power line communication line 100 and configured to communicate with the slave control device 300 through the power line communication line 100 and to control and monitor the slave control device 300, and a filter unit 410 disposed on the power line communication line 100 and configured to block the communication signal such that the communication signal is prevented from leaving a power-communication signal applied section 120 and entering a power applied section 110.

The filter unit 410 may be, for example, a low pass filter (LPF), which passes only a signal of a frequency corresponding to the power, or a band stop filter (BSF), which blocks a signal corresponding to a frequency band corresponding to the communication signal.

Here, based on the filter unit 410, the power applied section 110 in which only the power is applied and the power-communication signal applied section 120 in which the power and the communication signal are applied are formed on the power line communication line 100. The slave control device 300 and the master control device 200 are connected to the power-communication signal applied section 120 of the power line communication line 100. In the semiconductor process logistics management system 1 according to the present embodiment, the power applied section 110 in which only the power is supplied and the power-communication signal applied section 120 are separated from each other by the filter unit 410, whereby the communication signal other than the power may be prevented from being introduced into a noise-sensitive external device (e.g., a semiconductor process device, etc.) and causing the malfunction of the device.

The master control device 200 controls the slave control device 300 by receiving a control signal from an external server 500, monitors the operation state of the slave control device 300, and delivers the monitoring data to the external server 500. Here, the master control device 200 may be connected to the external server 500 through a communication line 600, and the communication line 600 may be a wired communication line, such as a LAN, etc., or a wireless communication line, such as Wi-Fi or WLAN, but is not limited thereto.

More specifically, the master control device 200 includes a master-side power line communication module 210 configured to separate the power and the communication signal supplied from the power-communication signal applied section 120 of the power line communication line 100 and to transmit and receive the communication signal to and from the power line communication line 100, a master-side power supply module 220 configured to receive the power from the master-side power line communication module 210, a master-side central control module 260 configured to control the master control device 200, and a master-side communication module 240 connected to the external server 500 and configured to receive a control signal from the outside. Also, the master control device 200 may include an external power supply module 230 and a master-side sensor module 250.

The external power supply module 230 may supply operation power to the master control device 200 through an external power supply unit (not illustrated) attached to the outside when power is not supplied to the master control device 200 through the power line communication line 100 due to malfunction in the master-side power supply module 220 of the master control device 200 or malfunction in the power line communication line 100 connected to the master-side power line communication module 210 during operation. Here, the separate external power supply unit attached to the outside may be an uninterruptible power supply (UPS), a BAT, or the like.

The master-side sensor module 250 provides an interface for processing various sensors for diagnosing malfunction in the power supply of the master control device 200 and the power line communication module 210, malfunction in the communication module 240, and the state and failure of components constituting a rail or logistics system, and the interface may be formed of an insulated structure or a non-insulated structure.

Here, the master-side power line communication module 210 includes a coupler unit 211 configured to receive the power and the communication signal from the power line communication line 100 and to supply the power to the master-side power supply module 220 and a master-side power line communication transceiver unit 212 configured to receive the communication signal from the coupler unit 211 or to deliver the communication signal to the coupler unit 211.

The coupler unit 211 serves to protect the device from an electrical (current or voltage) surge and to separate noise (switching noise, and other communication signals), which flows in from the power supply unit, from the communication signal, and may also suppress the direct inflow of the communication signal to the master-side power supply module 220.

Here, the coupler unit 211 may include a low pass filter (LPF) for passing the power and a band pass filter (BPF) or high pass filter (HPF) for passing the communication signal. Here, the power and the communication signal are individually delivered to the master-side power supply module 220 and the master-side power line communication transceiver unit 212, respectively.

Meanwhile, the slave control device 300 is controlled by receiving a control signal from the master control device 200 and delivers data about the operation state, etc. to the master control device 200.

More specifically, the slave control device 300 may include an identification module 330 capable of communicating with the identification tag of the item stored in the item storage device 900, a slave-side power line communication module 310 configured to separate the power and the communication signal supplied from the power-communication signal applied section 120 of the power line communication line 100 and to transmit and receive the communication signal, a slave-side power supply module 320 configured to receive the power from the slave-side power line communication module 310, a gas supply control module 340 configured to control the supply of inert gas for the item storage device 900, a slave-side central control module 360 configured to control the identification module 330 and the gas supply control module 340, and a slave-side sensor module 350.

The slave-side sensor module 350 provides an interface for processing various sensors for diagnosing malfunction in the power supply of the slave control device 300 and the power line communication module 310, malfunction in the gas supply control module 340, and the state and failure of components constituting a rail or logistics system, and the interface may be formed of an insulated structure or a non-insulated structure.

The slave-side power line communication module 310 includes a coupler unit 311 configured to receive the power and the communication signal from the power line communication line 100 and to supply the power to the slave-side power supply module 320 and a slave-side power line communication transceiver unit 312 configured to receive the communication signal from the coupler unit 311 or to deliver the communication signal to the coupler unit 311. The coupler unit 311 of the slave-side power line communication module 310 is substantially the same as the coupler unit 211 of the master-side power line communication module 210, thus a detailed description thereof will be omitted. Also, the identification module 330 includes one or more antenna units 332 on the identification module side, which are configured to perform wireless communication with the identification tag of the item, and an identification module control unit 331 configured to supply power to the identification tag and transmit and receive an identification signal through the antenna unit 332 on the identification module side. Here, the identification tag may be, for example, an RFID, and the identification module control unit 331 may communicate with the identification tag by controlling the antenna unit 332 on the identification module side.

For example, the identification module control unit 331 may perform data communication and power transmission using a first frequency and perform power transmission using a second frequency, and includes a carrier wave generation block 333 configured to generate a carrier wave and a control command, an antenna selection block 336 configured to designate any one of the connected one or more antenna units on the identification module side and to select a port to which the antenna unit is connected, a power monitoring block 334 configured to monitor the power transmitted from the antenna unit, and a capacitor selection block 335 configured to match the impedance that varies due to an external influence and a coil value deviation in the antenna unit.

In the present embodiment, the capacitor selection block 335 for impedance matching includes multiple capacitors, and may 1) select a capacitor so as to maximize the current or resonance voltage applied to the antenna unit 332 on the identification module side such that the maximum power is transmitted through the antenna unit 332 on the identification module side or 2) select a capacitor to reduce the difference between the voltage phase and current phase of a transmitter switching circuit.

Meanwhile, the identification module control unit 331 further includes a storage unit in which information about the capacitor selected for impedance matching and information about the antenna selected in the antenna unit 332 on the identification module side are stored. The storage unit may store information about the association of the antenna with the capacitor for transmitting the maximum power at the time of impedance matching and the voltage or phase information measured by the association.

Also, the identification module control unit 331 may further include a detection unit, which is configured to detect a difference between a preset voltage or phase and a voltage or phase detected during operation when a capacitor associated with each antenna to transmit the maximum power to the antenna is selected and power is transmitted through the carrier wave generation block 333, and a malfunction determination unit, which is configured to determine the malfunction of the antenna or abnormal operation when the phase difference detected by the detection unit exceeds a preset reference deviation range.

In the present embodiment, impedance matching of the identification module control unit 331 may comprise searching for a capacitor having the highest value when the resonance frequency AC voltage, detected in the capacitor sequentially selected from the capacitor selection block for the antenna selected among the antennas of the antenna unit 332 on the identification module side, is converted into a DC voltage level, and storing the association of the selected antenna with the selected capacitor and the detected voltage.

When the antenna resonance characteristics are changed due to metal and other external factors, the transmission power is lowered, which affects reading performance, but the state in which the optimal transmission power is output in the environment may be found by performing a tuning process for the transmission signal at the time of initial installation, and the maximum performance may be secured using the corresponding value.

Based thereon, the transmission power is adjusted in the form of open loop power control, whereby it is possible to respond to cases in which low power is required. Accordingly, when an external device sensitive to a frequency exists in the vicinity, it is possible to respond thereto by adjusting the carrier wave transmission power to be low within the range in which communication is possible.

According to the proposed embodiment, the power supply and communication are performed through a power line, which is a power supply line, in the semiconductor process logistics management system, so there is no need for working at height for installation of expensive communication cables for conventional communication, and in addition, a general-purpose PC or a universal controller (an MCU, etc.) can be used instead of an EtherCAT-specific control system (a BeckHoff PC, etc.), so the overall cost may be reduced.

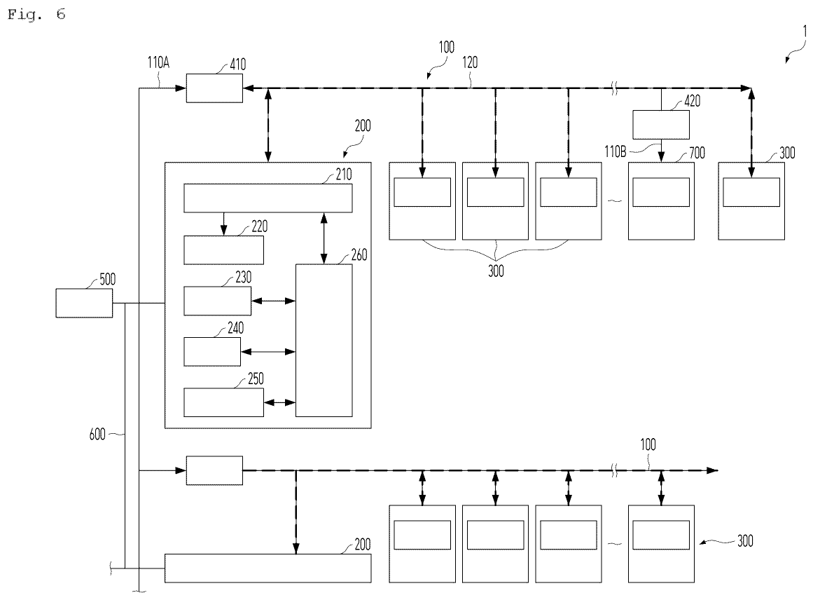

FIG. 6 is a diagram illustrating a semiconductor process logistics management system according to another embodiment of the present disclosure.

The present embodiment differs only in the configuration of the filter unit, and the other configurations are substantially the same as the configurations of the semiconductor process logistics management system of FIGS. 1 to 4, so the present embodiment will be described below with focus on the distinctive part thereof.

Referring to FIG. 6, the filter unit according to the present embodiment comprises multiple filter units 410 and 420, which include the first filter unit 410 and the second filter unit 420.

More specifically, the power-communication signal applied section 120 of the power line communication line 100 is provided between the first power applied section 110A and second power applied section 110B of the power applied section 110.

Also, the first filter unit 410 is disposed in a node to which the power-communication signal applied section 120 and the first power applied section 110A are connected, and the second filter unit 420 is disposed in a node to which the power-communication signal applied section 120 and the second power applied section 110B are connected.

Also, an external device 700 that receives only the power from the power line communication line 100 is connected to the second power applied section 110B.

That is, the second filter unit 420 is disposed between the node via which the external device 700 is connected to the power line communication line and the node via which the master control device 200 or the slave control device 300 is connected to the power line communication line 100, whereby the inflow of the communication signal to the external device 700 may be prevented.

The second filter unit 420 has the same structure as the first filter unit 410.

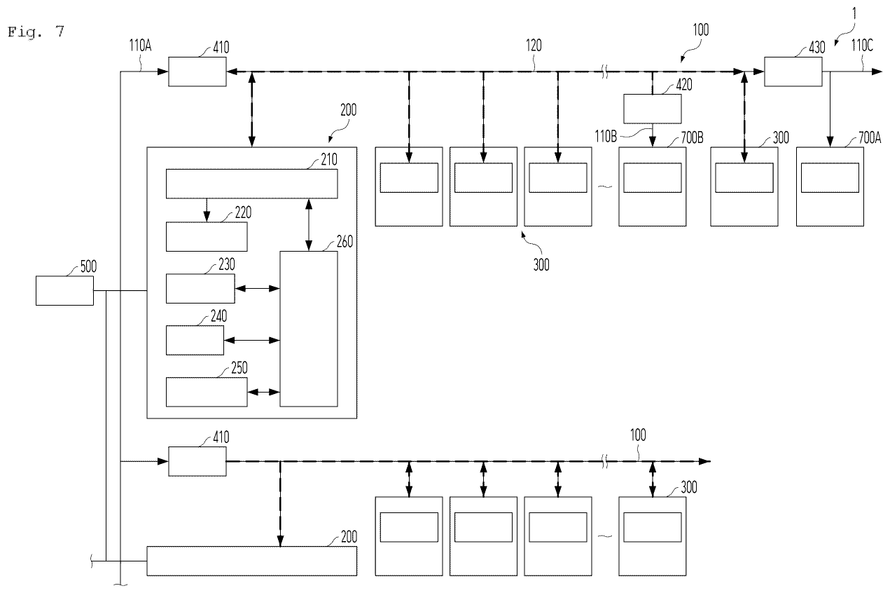

FIG. 7 is a diagram illustrating a semiconductor process logistics management system according to a further embodiment of the present disclosure.

The present embodiment differs only in the arrangement of the filter unit, and the other configurations are substantially the same as the configurations of the semiconductor process logistics management system of FIG. 6, so the present embodiment will be described below with focus on the distinctive part thereof.

Referring to FIG. 7, the semiconductor process logistics management system 1 according to the present embodiment includes a first filter unit 410, a second filter unit 420, and a third filter unit 430.

The first filter unit 410 and the third filter unit 430 are symmetrically disposed at one end and the other end of the applied power-communication signal applied section 120 of the power line communication line 100 such that the communication signal in the power-communication signal applied section 120 is more stably formed.

The third filter unit 430 has the same structure as the first filter unit 410.

Also, the second filter unit 420 is disposed in the node connected to the second power applied section 110B and the power-communication signal applied section 120 such that the second power applied section 110B, branching from the power-communication signal applied section 120, is formed to be connected to a second external device 700B. Meanwhile, a first external device 700A may be connected to the third power applied section 110C.

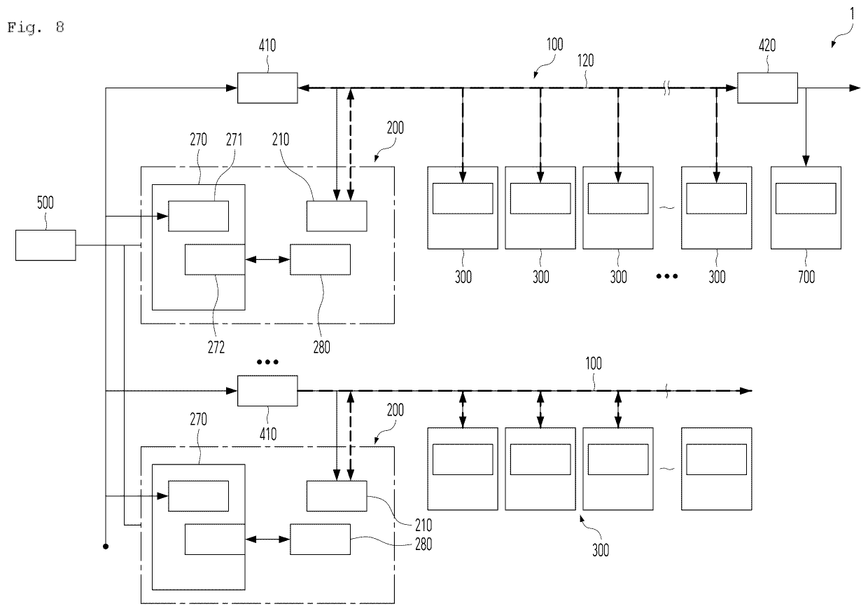

FIG. 8 is a diagram illustrating a semiconductor process logistics management system according to yet another embodiment of the present disclosure.

The present embodiment differs only in the configuration of the master control device, and the other configurations are substantially the same as the configurations of the semiconductor process logistics management system illustrated in FIGS. 1 to 7, so the present embodiment will be described below with focus on the distinctive part thereof.

Referring to FIG. 8, the master control device 200 of the semiconductor process logistics management system 1 according to the present embodiment further includes a control signal transceiver module 270 connected to the external server 500 and configured to receive a control signal from the external server 500 and to deliver a monitoring signal to the external server 500. The control signal transceiver module 270 may be a commercial PC or universal controller (an MCU, etc.) connected to an external communication line, e.g., a wired communication line, such as a LAN, etc., or a wireless communication line, such as Wi-Fi, etc. The control signal transceiver module 270 includes a power supply unit 271 on the control signal transceiver module side, which is connected to the power applied section of the power line communication line and configured to receive the power, and a communication unit 272 on the control signal transceiver module side, which is configured to transmit and receive the control signal. Also, the master control device 200 further includes a master-side communication unit 280 configured to transmit and receive the control signal to and from the control signal transceiver module 270.

The control signal transceiver module 270 may be installed inside or outside the master control device 200.

Because the control signal transceiver module 270 according to the present embodiment may be a commercial PC or universal controller (an MCU, etc.) using an external power supply, it may be more easily installed and have the effect of reducing the installation cost.

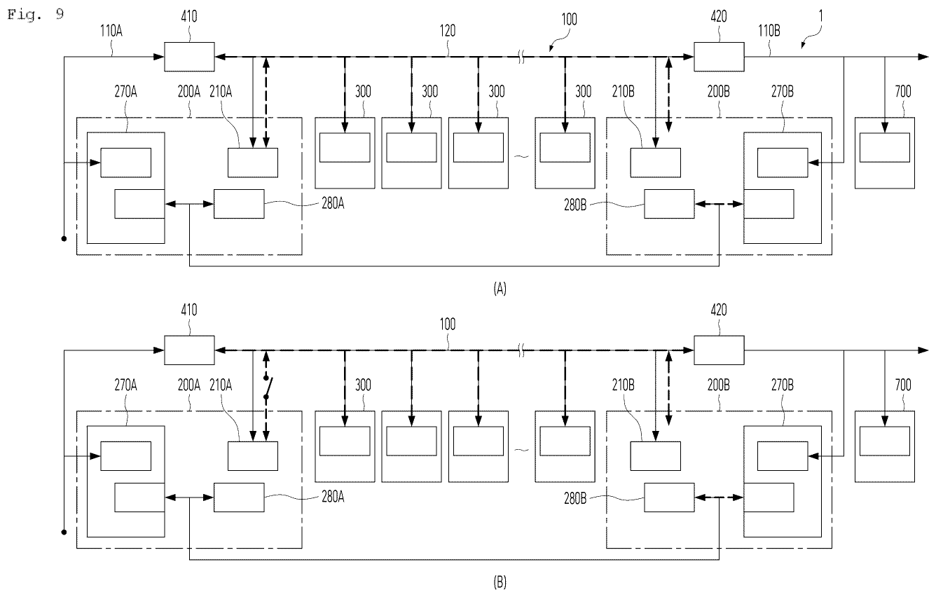

FIG. 9 is a diagram illustrating a semiconductor process logistics management system according to still another embodiment of the present disclosure.

The present embodiment differs only in the disposition of the master control device, and the other configurations are substantially the same as the configurations of the semiconductor process logistics management system illustrated in FIGS. 1 to 8, so the present embodiment will be described below with focus on the distinctive part thereof.

Referring to FIGS. 9(A) and 9(B), the master control device 200 of the semiconductor process logistics management system 1 according to the present embodiment includes a first master control device 200A connected to the first node of the power line communication line 100 and a second master control device 200B connected to the second node formed at a location different from the location of the first node to which the first master control device 200A is connected.

Only one of the first master control device 200A and the second master control device 200B performs communication with the slave control device 300, and the other one monitors whether the master control device 200 performing communication with the slave control device 300 normally operates.

When the master control device 200 performing communication with the slave control device 300 does not perform normal operation, the master control device 200 performing communication with the slave control device 300 blocks the transmission and reception of communication by disconnecting the connection of the power line communication signal switch that is connected to the power line communication line 100, and the other master control device 200 connects the power line communication signal switch, which is connected to the power line communication line 100, to enable the transmission and reception of communication and starts communication with the slave control device 300.

For example, in the present embodiment, when the first master control device 200A transmits and receives signals to and from the slave control devices 300 in the state in which both the first master control device 200A and the second master control device 200B are connected to the power line communication line 100, the second master control device 200B monitors the operation state of the first master control device 200A.

Then, when the first master control device 200A fails to perform normal operation, the first master control device 200A disconnects the connection of the first master power line communication signal switch connected to the power line communication line 100 and blocks the transmission and reception of communication, and the second master control device 200B, which monitors the communication of the first master control device 200A, initiates a connection of the second master power line communication signal switch connected to the power line communication line 100 and starts the transmission and reception of signals with the slave control devices 300. Here, the second master control device 200B may deliver to an external server, the abnormal operation state of the first master control device 200A and the disconnection of the first master control device 200A from the power line communication line.

In the present embodiment, multiple master control devices 200 are provided, and when malfunction occurs in the main master control device 200A, another master control device 200B immediately performs the corresponding role. Accordingly, the occurrence of a system failure may be minimized, and the recovery time may be minimized in the event of a failure.

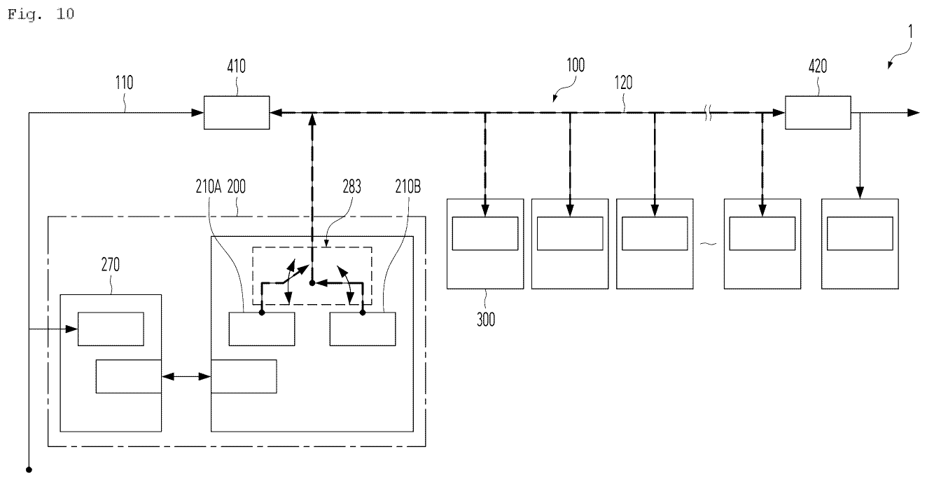

FIG. 10 is a diagram illustrating a semiconductor process logistics management system according to still another embodiment of the present disclosure.

The present embodiment differs only in the configuration of the master control device, and the other configurations are substantially the same as the configurations of the semiconductor process logistics management system illustrated in FIGS. 1 to 7, so the present embodiment will be described below with focus on the distinctive part thereof.

Referring to FIG. 10, the master control device 200 according to the present embodiment may include multiple master-side power line communication modules 210A and 210B.

Here, the master control device 200 includes a switching module 283 configured to selectively connect any one of the multiple master-side power line communication modules to the power line communication line.

In the present embodiment, multiple master-side power line communication modules are provided in the master control device 200, and when a problem occurs in the master-side power line communication module connected to the power line communication line 100, this is detected, and another master-side power line communication module is connected to the power line communication line 100. Accordingly, it is possible to quickly restore the function in the event of a failure.

Although the present embodiment is described with focus on the configuration of the master control 1 device 200, a configuration including multiple power line communication modules and configured to detect an abnormal state of any one power line communication module and to selectively block the power and the communication signal may be applied also to the slave control device 300.

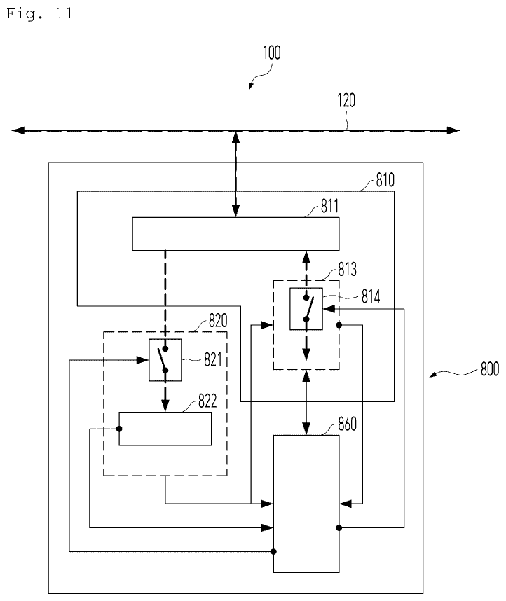

FIG. 11 is a diagram illustrating the master control device of a semiconductor process logistics management system according to still another embodiment of the present disclosure.

The present embodiment differs in the configuration of the master control device 800, and the other configurations are substantially the same as the configurations of the semiconductor process logistics management system illustrated in FIGS. 1 to 7, so the present embodiment will be described below with focus on the distinctive part thereof.

Referring to FIG. 11, the master-side power line communication transceiver unit 813 of the master-side power line communication module 810 includes a switching unit 814 on the communication unit side, which is configured to selectively block the communication signal delivered from the coupler unit 811.

Also, the master-side power line communication transceiver unit 813 delivers power line communication monitoring data about the communication signal to the master-side central control module 860, and the master-side central control module 860 determines whether the communication signal is normal or abnormal based on the power line communication monitoring data. When the communication signal is determined to be abnormal, the master-side central control module 860 transmits a communication signal blocking control signal to the master-side power line communication transceiver unit 813 such that the switching unit 814 on the communication unit side blocks the communication signal.

Meanwhile, the master-side power supply module 820 includes a switching unit 821 on the power supply module side, which is configured to selectively block the power delivered from the coupler unit 811, and a power monitoring unit 822 configured to generate power monitoring data about the state of the power and to deliver the power monitoring data to the master-side central control module.

The master-side central control module 860 determines whether the power is normal or abnormal based on the power monitoring data. When the power is determined to be abnormal, the master-side central control module 860 transmits a power blocking control signal to the master-side power supply module 820 such that the switching unit 821 on the power supply module side blocks the power.

Here, the switching unit 821 on the power supply module side and the switching unit 814 on the communication unit side may block the power supply and the communication signal independently of each other.

In the present embodiment, when an unexpected surge or the like occurs through the power line communication line, the master-side central control module 860 of the master control device 800 detects it and performs blocking of the power or the communication signal, thereby protecting the internal circuit configuration and robustly responding to the failure.

Although the present embodiment is described with focus on the configuration of the master control device, the configuration for detecting an abnormal state and selectively blocking the power and the communication signal may be applied also to the slave control device 300.

In the master control device 800 of the present disclosure, there may be provided an external power supply module configured to supply operation power to the master control device 800 through an external power supply unit (not illustrated) when the power supply to the master-side power supply module 820 is blocked by the switching unit 821 on the power supply module side.

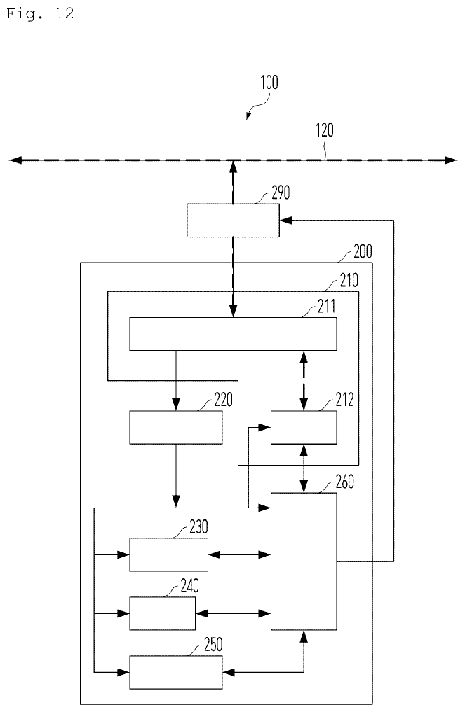

FIG. 12 is a diagram illustrating the master control device of a semiconductor process logistics management system according to still another embodiment of the present disclosure.

The present embodiment differs only in the configuration of the master control device 200, and the other configurations are substantially the same as the configurations of the semiconductor process logistics management system illustrated in FIGS. 1 to 7, so the present embodiment will be described below with focus on the distinctive part thereof.

Referring to FIG. 12, the master control device 200 of the semiconductor process logistics management system 1 according to the present embodiment further includes a master-side switching unit 290 configured to selectively block the power and the communication signal, delivered from the power line communication line 100 to the master-side power line communication module 210.

The master-side power supply module 220, which receives the power from the coupler unit 211, generates power monitoring data about the state of the power and delivers the power monitoring data to the master-side central control module 260.

The master-side power line communication transceiver unit 212 delivers power line communication monitoring data about the communication signal to the master-side central control module 260.

Also, the master-side central control module 260 determines whether the power is normal or abnormal based on the power monitoring data and determines whether the communication signal is normal or abnormal based on the power line communication monitoring data.

Although the present embodiment is described with focus on the configuration of the master control device 200, the configuration for detecting an abnormal state and selectively blocking the power and the communication signal may be applied also to the slave control device 300.

When it is determined that at least one of the power and the communication signal is abnormal, the master-side central control module 260 transmits a blocking control signal to the master-side switching unit 290 such that the master-side switching unit 290 blocks the power and the communication signal supplied from the power line communication line to the master-side power line communication module.

Meanwhile, the present embodiment describes a configuration in which the master control device 200 includes the master-side switching unit 290, but a configuration in which the slave control device 300 includes a slave-side switching unit may also be included in the embodiment of the present disclosure.

According to the proposed embodiment, there is an advantage in which, in the event of an unexpected surge in the power line communication line 100, it may be quickly detected to protect the circuit.

According to the proposed embodiment, because power supply and communication are performed through a power line, which is a power supply line, there is no need for expensive communication cables for communication, which may reduce installation costs and eliminate the need for working at height for installation of communication cables. In addition, it is possible to use a general-purpose PC or a universal controller (a microcontroller unit (MCU), etc.), instead of an EtherCAT-specific control system (a BeckHoff PC, etc.), so the overall cost may be reduced.

Although embodiments of the present disclosure have been described above, the present disclosure is not limited thereto and may be modified and practiced in any form within the scope of the claims, the detailed description of the present disclosure, and the accompanying drawings, and it is apparent that the modifications also fall within the scope of the present disclosure.

What is claimed is:

1. A semiconductor process logistics management system, comprising:
a slave control device configured to perform control for an item storage device in which an item is stored;
a power line communication line configured to deliver power and a communication signal to the slave control device;
a master control device connected to the power line communication line and configured to communicate with the slave control device through the power line communication line; and
a filter unit disposed on the power line communication line and configured to block the communication signal,
wherein, based on the filter unit, a power applied section in which only the power is applied and a power-communication signal applied section in which the power and the communication signal are applied are formed on the power line communication line.

2. The semiconductor process logistics management system of claim 1, wherein:
the slave control device and the master control device are connected to the power-communication signal applied section of the power line communication line,
the slave control device includes a slave-side power line communication module configured to separate the power and the communication signal supplied from the power line communication line and to transmit and receive the communication signal, and
the master control device includes a master-side power line communication module configured to separate the power and the communication signal supplied from the power line communication line and to transmit and receive the communication signal to and from the power line communication line.

3. The semiconductor process logistics management system of claim 2, wherein:
the slave control device further includes an identification module capable of communicating with an identification tag of the item stored in the item storage device, a slave-side power supply module configured to receive the power from the slave-side power line communication module, a gas supply control module configured to control supply of inert gas for the item storage device, a slave-side central control module configured to control the identification module and the gas supply control module, and a slave-side sensor module configured to sense states of components,
the slave-side power line communication module includes a coupler unit configured to receive the power and the communication signal from the power line communication line and to supply the power to the slave-side power supply module and a slave-side power line communication transceiver unit configured to receive the communication signal from the coupler unit or to deliver the communication signal to the coupler unit, and
the identification module includes one or more antenna units on an identification module side, configured to perform wireless communication with the identification tag, and an identification module control unit configured to supply power to the identification tag and to transmit and receive an identification signal through the antenna unit on the identification module side.

4. The semiconductor process logistics management system of claim 3, wherein the identification module control unit includes a carrier wave generation block configured to generate a carrier wave and a control command, an antenna selection block configured to designate any one of the connected one or more antenna units on the identification module side and to select a port to which the antenna unit is connected, a power monitoring block configured to monitor power transmitted from the antenna unit, and a capacitor selection block configured to match impedance that varies due to an external influence and a coil value deviation in the antenna unit.

5. The semiconductor process logistics management system of claim 3, wherein:
the slave control device further includes a slave-side switching unit configured to selectively block the power and the communication signal delivered from the power line communication line to the slave-side power line communication module,
the slave-side power supply module, which receives the power from the coupler unit, generates power monitoring data about a state of the power and delivers the power monitoring data to the slave-side central control module,
the slave-side power line communication transceiver unit delivers power line communication monitoring data about the communication signal to the slave-side central control module,
the slave-side central control module determines whether the power is normal or abnormal based on the power monitoring data and determines whether the communication signal is normal or abnormal based on the power line communication monitoring data, and
the slave-side central control module transmits a blocking control signal to the slave-side switching unit such that the slave-side switching unit blocks the power and the communication signal, supplied from the power line communication line to the slave-side power line communication module, when at least one of the power and the communication signal is determined to be abnormal.

6. The semiconductor process logistics management system of claim 3, wherein:
the slave-side power line communication module comprises multiple slave-side power line communication modules, each of which is individually connected to the slave-side power supply module and the slave-side central control module, and
the slave control device includes a switching module configured to selectively connect any one of the multiple slave-side power line communication modules to the power line communication line.

7. The semiconductor process logistics management system of claim 2, wherein:
the master control device further includes a master-side power supply module configured to receive the power from the master-side power line communication module, a master-side central control module configured to control the master control device, an external power supply module configured to selectively receive power from an external power supply unit, and a master-side sensor module configured to sense states of components, and
the master-side power line communication module includes a coupler unit configured to receive the power and the communication signal from the power line communication line and to supply the power to the master-side power supply module and a master-side power line communication transceiver unit configured to receive the communication signal from the coupler unit or to deliver the communication signal to the coupler unit.

8. The semiconductor process logistics management system of claim 7, wherein the master control device further includes a master-side communication module connected to an external server and configured to receive a control signal from the external server.

9. The semiconductor process logistics management system of claim 7, wherein:
the master control device further includes a control signal transceiver module connected to an external server and configured to receive a control signal from the external server,
the control signal transceiver module includes a power supply unit on a control signal transceiver module side, connected to the power applied section of the power line communication line and configured to receive the power, and a communication unit on the control signal transceiver module side, configured to transmit and receive the control signal, and
the master control device further includes a master-side communication unit configured to transmit and receive the control signal to and from the control signal transceiver module.

10. The semiconductor process logistics management system of claim 8, wherein:
the master-side power line communication module comprises multiple master-side power line communication modules, each of which is individually connected to the master-side power supply module and the master-side central control module, and
the master control device further includes a switching module configured to selectively connect any one of the multiple master-side power line communication modules to the power line communication line.

11. The semiconductor process logistics management system of claim 7, wherein:
the master-side power line communication transceiver unit of the master-side power line communication module includes a switching unit on a communication unit side, configured to selectively block the communication signal delivered from the coupler unit,
the master-side power line communication transceiver unit delivers power line communication monitoring data about the communication signal to the master-side central control module,
the master-side central control module determines whether the communication signal is normal or abnormal based on the power line communication monitoring data, and
the master-side central control module transmits a communication signal blocking control signal to the master-side power line communication transceiver unit such that the switching unit on the communication unit side blocks the communication signal when the communication signal is determined to be abnormal.

12. The semiconductor process logistics management system of claim 11, wherein:
the master-side power supply module includes a switching unit on a power supply module side, configured to selectively block the power delivered from the coupler unit, and a power monitoring unit configured to generate power monitoring data about a state of the power and to deliver the power monitoring data to the master-side central control module,
the master-side central control module determines whether the power is normal or abnormal based on the power monitoring data,
the master-side central control module transmits a power blocking control signal to the master-side power supply module such that the switching unit on the power supply module side blocks the power when the power is determined to be abnormal, and
the switching unit on the power supply module side and the switching unit on the communication unit side block the power and the communication signal independently of each other.

13. The semiconductor process logistics management system of claim 8, wherein:
the master control device further includes a master-side switching unit configured to selectively block the power and the communication signal delivered from the power line communication line to the master-side power line communication module,
the master-side power supply module, which receives the power from the coupler unit, generates power monitoring data about a state of the power and delivers the power monitoring data to the master-side central control module,
the master-side power line communication transceiver unit delivers power line communication monitoring data about the communication signal to the master-side central control module,
the master-side central control module determines whether the power is normal or abnormal based on the power monitoring data and determines whether the communication signal is normal or abnormal based on the power line communication monitoring data, and
the master-side central control module transmits a blocking control signal to the master-side switching unit such that the master-side switching unit blocks the power and the communication signal, supplied from the power line communication line to the master-side power line communication module, when at least one of the power and the communication signal is determined to be abnormal.

14. The semiconductor process logistics management system of claim 1, wherein:
the power-communication signal applied section of the power line communication line is provided between a first power applied section and a second power applied section of the power applied section, and
the filter unit includes a first filter unit disposed in a node to which the power-communication signal applied section and the first power applied section are connected and a second filter unit disposed in a node to which the power-communication signal applied section and the second power applied section are connected.

15. The semiconductor process logistics management system of claim 14, further comprising:
an external device connected to the power line communication line of the power-communication signal applied section and configured to receive only the power,
wherein the filter unit includes a third filter unit between the external device and a node to which the power line communication line of the power-communication signal applied section is connected.

16. The semiconductor process logistics management system of claim 1, wherein:
the master control device includes a first master control device connected to any one node on the power line communication line and a second master control device connected to an additional node other than the node to which the first master control device is connected,
only any one of the first master control device and the second master control device performs communication with the slave control device,
a remaining one of the first master control device and the second master control device monitors whether the master control device performing communication with the slave control device normally operates, and
when the master control device performing communication with the slave control device does not perform normal operation, connection of the master control device performing communication with the slave control device to the power line communication line is disconnected and the remaining master control device starts communication with the slave control device.

17. A slave control device configured to perform control for an item storage device in which an item is stored, comprising:
a slave-side power line communication module configured to separate power and a communication signal supplied from a power line communication line and to transmit t and receive the communication signal;
a slave-side power supply module configured to receive the power from the slave-side power line communication module; and
a slave-side sensor module configured to sense states of components,
wherein the slave-side power line communication module includes a coupler unit configured to receive the power and the communication signal from the power line communication line and to supply the power to the slave-side power supply module and a slave-side power line communication transceiver unit configured to receive the communication signal from the coupler unit or to deliver the communication signal to the coupler unit.

18. The slave control device of claim 17, further comprising:
a gas supply control module configured to control supply of inert gas for the item storage device;
an identification module capable of communicating with an identification tag of the item stored in the item storage device; and
a slave-side central control module configured to control the identification module and the gas supply control module,
wherein the identification module includes one or more antenna units on an identification module side, configured to perform wireless communication with the identification tag, and an identification module control unit configured to supply power to the identification tag and transmit and receive an identification signal through the antenna unit on the identification module side.

19. The slave control device of claim 18, wherein the identification module control unit includes a carrier wave generation block configured to generate a carrier wave and a control command, an antenna selection block configured to designate any one of the connected one or more antenna units on the identification module side and to select a port to which the antenna unit is connected, a power monitoring block configured to monitor power transmitted from the antenna unit, and a capacitor selection block configured to match impedance that varies due to an external influence and a coil value deviation in the antenna unit.

20. A master control device configured to communicate with a slave control device, which performs control for an item storage device in which an item is stored, through a power line communication line, comprising:
a master-side power line communication module configured to separate power and a communication signal supplied from the power line communication line and to transmit and receive the communication signal to and from the power line communication line;
a master-side power supply module configured to receive the power from the master-side power line communication module;
a master-side central control module configured to control the master control device;
an external power supply module configured to selectively receive power from an external power supply unit; and
a master-side sensor module configured to sense states of components,
wherein the master-side power line communication module includes a coupler unit configured to receive the power and the communication signal from the power line communication line and to supply the power to the master-side power supply module and a master-side power line communication transceiver unit configured to receive the communication signal from the coupler unit or to deliver the communication signal to the coupler unit.

21. The master control device of claim 20, further comprising:
a master-side communication module connected to an external server and configured to receive a control signal from the external server.

22. The master control device of claim 20, further comprising:
a control signal transceiver module connected to an external server and configured to receive a control signal from the external server; and
a master-side communication unit configured to transmit and receive the control signal to and from the control signal transceiver module,
wherein the control signal transceiver module includes a power supply unit on a control signal transceiver module side, connected to a power applied section of the power line communication line and configured to receive the power, and a communication unit on the control signal transceiver module side, configured to transmit and receive the control signal.

23. The master control device of claim 20, wherein:
the master-side power line communication module comprises multiple master-side power line communication modules, each of which is individually connected to the master-side power supply module and the master-side central control module, and
the master control device further includes a switching module configured to selectively connect any one of the multiple master-side power line communication modules to the power line communication line.
